(19) United States
(12) Patent Application Publication
(10) Pub. No.: US 2022/0216839 A1
(43) Pub. Date: Jul. 7, 2022

(54) STABILIZING COMMON MODE OF DIFFERENTIAL SWITCHING OUTPUT STAGE

(71) Applicant: Analog Devices International Unlimited Company, Limerick (IE)

(72) Inventors: Naoaki NISHIMURA, Tokyo (JP); Atsushi MATAMURA, Tokyo (JP); Abhishek BANDYOPADHYAY, Winchester, MA (US); Mariana Tosheva MARKOVA, Cambridge, MA (US)

(73) Assignee: Analog Devices International Unlimited Company, Limerick (IE)

(21) Appl. No.: 17/702,025

(22) Filed: Mar. 23, 2022

Related U.S. Application Data
(63) Continuation of application No. PCT/EP2020/076671, filed on Sep. 24, 2020.
(60) Provisional application No. 62/905,364, filed on Sep. 24, 2019.

(51) Int. Cl. H03F 3/45

(52) U.S. Cl. CPC H03F 3/45269

(57) ABSTRACT

Differential switching output stage for audio, power and digital data transmission can cause a common mode error due to asymmetric transition between positive and negative outputs. Systems and methods are provided for common mode error correction. In particular, summing nodes, novel error amps an edge switching can be used for common-mode feedback (CMFB) in differential signaling and other applications.

### CROSS-REFERENCE TO RELATED APPLICATIONS

This application is related to and claims the benefit of priority under 35 U.S.C. § 119(e) to International Patent Application No. PCT/EP2020/076671 entitled, “STABILIZING COMMON MODE OF DIFFERENTIAL SWITCHING OUTPUT STAGE” filed Sep. 24, 2020 and U.S. Provisional Patent Application No. 62/905,364 entitled, “STABILIZING COMMON MODE OF DIFFERENTIAL SWITCHING OUTPUT STAGE” filed on Sep. 24, 2019, which are hereby incorporated by reference in their entirety.

### FIELD OF THE DISCLOSURE

The present disclosure relates to differential switching amplifiers. More specifically, this disclosure describes apparatuses and systems for common mode error correction.

### BACKGROUND

Differential signaling is a method for electrically transmitting information using two complementary signals. The technique sends the same electrical signal as a differential pair of signals, each in its own conductor. The pair of conductors can be wires (typically twisted together) or traces on a circuit board. The receiving circuit responds to the electrical difference between the two signals, rather than the difference between a single wire and ground. The opposite technique is called single-ended signaling. Differential pairs are usually found on printed circuit boards, in twisted-pair and ribbon cables, and in connectors.

Differential signaling is a way of transmitting a differential signal from a transmitter to a receiver via a differential transmission line, e.g., via a pair of wires, e.g., copper wires. A differential signaling driver circuit drives an electrical current through the transmission line in accordance with a driver signal. The electrical current in the transmission line is referred to herein as the signal current. The driver signal may, for example, be provided by a voltage, an electrical current or any other suitable physical quantity.

A differential signaling receiver circuit may comprise a resistive bridge connected across the differential output of the transmission line, i.e., between the two conductors of the transmission line at the end of the transmission line. The electrical current injected into the transmission line by the differential signaling driver circuit thus translates into a voltage across the resistive bridge at the end of the transmission line. This voltage may be further processed or analyzed by the differential signaling receiver circuit or by circuitry connected to the differential signaling receiver circuit.

The driver signal is usually a bi-level signal, i.e. a binary signal. However, a differential signaling driver circuit may, in principle, be capable of translating any kind of waveform of the driver signal into a corresponding waveform of the signal current. In other words, a differential signaling driver circuit may be suitable for both continuous (i.e., analog) and discrete (i.e., digital) driver signals.

Differential signaling may be performed in a low-voltage manner when a differential signal of low voltage amplitude is superimposed on a common mode DC voltage. For example, a differential signal with a maximum amplitude of 0.5 V or less, e.g. 350 mV may be imposed on a common mode voltage of 1.5 V or less, such as 1.2 V or less, e.g. 0.9 V or less, e.g. 0.4 V. This is generally referred to as low-voltage differential signaling.

One of the advantages of differential signaling is reduction of electromagnetic emission. This is because the current flows in opposite directions through the pair wires for transmitting the signals, and the binary data “0” and “1” are different only in current direction and are equal in current amount. In addition, voltages caused by the resistor at the end of the wires do not change, although higher side of the signal lines changes depending on the signal values “0” or “1”. This also leads to a lower amount of electromagnetic emission.

However, the amount of electromagnetic emission is reduced only when the differential signals on the pair wires are switched substantially ideally. Actually, on switching the differential signals, there is a possibility that voltages of the signals are changed unequally or the directions of the currents flowing through the wires not change smoothly. They are mainly caused by a difference of ON/OFF timing in a plurality of transistors for generating the differential signals.

Depending on variations in manufacturing accuracy of a printed circuit, and variations in material, a delay time difference takes place between two transmission lines. The delay time difference between the two transmission lines is not so problematic when the bit rate is low. The higher the bit rate, the more severe the waveform distortion of a transmission signal becomes.

In particular, if a high-speed transmission or higher is performed, a time width of a signal waveform becomes short, and a delay time difference in excess of 1 unit interval (UI: one period of a bit clock) can take place over a travel distance of about tens of centimeters over a printed board. As a result, a margin of the time delay difference between the differential signals is reduced, and it is difficult to receive correctly a data signal. As a preventive step, a technique of detecting and then compensating for a skew of the differential signals on the receiver is used.

If the delay time difference is large between the transmission paths for transferring the differential signals in the above-described related art, it is difficult to maintain a differential state between the differential signals received by the receiver. It is thus difficult to detect the skew (phase difference) of the differential signals. The compensation for the skew of the differential signals is thus difficult, and an erratic operation may take place in a subsequent circuit of the receiver.

The inventors of the present invention have recognized a long felt need to correct for waveform and timing errors in differential signaling systems. This is accomplished in a common mode feedback approach which is highly versatile. These common-mode error cause EMI emissions and disturbances from a desired operation point of the circuit, etc.

This overview is intended to provide an overview of subject matter of the present patent application. It is not intended to provide an exclusive or exhaustive explanation of the invention. Further limitations and disadvantages of conventional and traditional approaches will become apparent to one of skill in the art, through comparison of such systems with some aspects of the present invention as set forth in the remainder of the present application with reference to the drawings.

### SUMMARY OF THE DISCLOSURE

System and apparatus for differential switching output stage for audio, power and digital data transmission can cause a common mode error due to asymmetric transition between positive and negative outputs. Common mode error produces problems of EMI or EMC. Audio performance degradation due to an operation point shift and data transmission error due to a distortion on the waveform.

According to one aspect, the present disclosure is an apparatus for a common-mode feedback circuit comprising a differential amplifier having a positive output and negative output a adder circuit configured to extract the common mode from the positive output and negative output, and a feedback amplifier configured to correct the common mode.

According to another aspect of the disclosure, the present disclosure further comprises a switching network, the switching network configured to control the correction of the common mode only during transitions in the differential amplifier.

According to another aspect of the disclosure, the present disclosure further comprises a common mode extractor circuit.

According to another aspect of the disclosure, the present disclosure further comprises an output stage.

According to another aspect of the disclosure, the present disclosure further contemplates wherein the adder circuit comprises two or more resistors wired in series.

According to another aspect of the disclosure, the present disclosure further contemplates wherein the adder circuit further comprises two more capacitors wired in series with one another and wired in parallel with the two or more resistors.

According to another aspect of the disclosure, the present disclosure further comprises a voltage reference source, the feedback amplifier is further configured to compare the voltage reference source with the common mode.

According to another aspect of the disclosure, the present disclosure further contemplates wherein the adder circuit comprises two or more capacitors wired in series.

According to another aspect of the disclosure, the present disclosure further contemplates wherein the adder circuit further comprises a resistor having one terminal wired in between the two or more capacitors wired in series.

The drawings show exemplary common mode stabilization for differential switching output circuits and configurations. Variations of these circuits, for example, changing the positions of, adding, or removing certain elements from the circuits are not beyond the scope of the present invention. The illustrated circuits, configurations, and complementary devices are intended to be complementary to the support found in the detailed description.

### BRIEF DESCRIPTION OF THE DRAWINGS

The present disclosure is best understood from the following detailed description when read with the accompanying figures. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

For a fuller understanding of the nature and advantages of the present invention, reference is made to the following detailed description of preferred embodiments and in connection with the accompanying drawings, in which:

FIG. 1A shows an exemplary graph illustrating asymmetry of switching a 2-level differential output, in accordance with some embodiments of the disclosure provided herein;

FIG. 1B shows an exemplary graph illustrating asymmetry of switching a 3-level differential output, in accordance with some embodiments of the disclosure provided herein;

FIG. 2 is an exemplary circuit demonstrating LVDS common mode feedback, in accordance with some embodiments of the disclosure provided herein;

FIG. 3 is an exemplary circuit demonstrating common-mode free binary modulation, in accordance with some embodiments of the disclosure provided herein;

FIG. 4 is an exemplary circuit demonstrating common-mode feedback (CMFB) during edge transition in a 3-level signaling system including sharing one error amp by using a multiplex switch, in accordance with some embodiments of the disclosure provided herein;

FIG. 5 illustrates an exemplary graph and corresponding timing table of edge transition in 3-level signaling system, in accordance with some embodiments of the disclosure provided herein;

FIG. 6 is an exemplary circuit demonstrating common-mode feedback (CMFB) during edge transition in a 3-level signaling system, in accordance with some embodiments of the disclosure provided herein;

FIG. 7 is an exemplary circuit demonstrating common-mode extraction using a resistor network, in accordance with some embodiments of the disclosure provided herein;

FIG. 8 is an exemplary circuit demonstrating common-mode extraction using a capacitor network, in accordance with some embodiments of the disclosure provided herein;

FIG. 9 is an exemplary circuit depicting an error amplifier implementation, in accordance with some embodiments of the disclosure provided herein;

FIG. 10 is an exemplary circuit depicting an error amplifier implementation, in accordance with some embodiments of the disclosure provided herein;

FIG. 11 is an exemplary circuit demonstrating common-mode feedback (CMFB) during edge transition in a 3-level signaling system using a parallel controller, in accordance with some embodiments of the disclosure provided herein;

FIG. 12 is an exemplary circuit demonstrating common-mode feedback (CMFB) during edge transitions in a 2-level signaling system, in accordance with some embodiments of the disclosure provided herein;

FIG. 13 is an exemplary summing node circuit which can be used in common-mode stabilization during edge transition in a 3-level signaling system, in accordance with some embodiments of the disclosure provided herein; and

FIG. 14 is an exemplary circuit configured to stabilizing a summing node by replicating of output stage and CMFB instead of controlling the output stage, in accordance with some embodiments of the disclosure provided herein.

### DETAILED DESCRIPTION

The present disclosure relates to differential switching amplifiers. More specifically, this disclosure describes apparatuses and systems for common mode error correction. In particular, summing nodes, novel error amps an edge switching can be used for common-mode feedback (CMFB) in differential signaling and other applications.

The following description and drawings set forth certain illustrative implementations of the disclosure in detail, which are indicative of several exemplary ways in which the various principles of the disclosure may be carried out. The illustrative examples, however, are not exhaustive of the many possible embodiments of the disclosure. Other objects, advantages and novel features of the disclosure are set forth in the proceeding in view of the drawings where applicable.

Embodiments herein relate to techniques to stabilize a common mode of a differential switching output stage which directly control the output switch on-resistance so as to keep the common mode stable. Embodiments may not use any of series devices on the output current path, and so may not limit an output swing or increase an output resistor. This may help the system operate with good power efficiency.

Generally, differential switching output stages for audio, power, or digital data transmission may cause a common mode error due to asymmetric transition between positive and negative outputs. The common mode error may result in electromagnetic interference (EMI) and/or electromagnetic compatibility (EMC). The common mode error may also cause audio performance degradation due to an operation point shift, or a data transmission error due to a distortion on the waveform. However, making the positive and negative outputs transition symmetry may be difficult because the transition may occur in a relatively short period, and keeping the timing over a wide process/voltage/temperature (PVT) range may be difficult.

Common mode feedback may mitigate the transition mismatch, but may be rarely used because of high power consumption based on high band-width. Additionally, common mode feedback may undesirable result in lowering output swing or increasing output impedance, which may be a drawback for power or class-D audio applications.

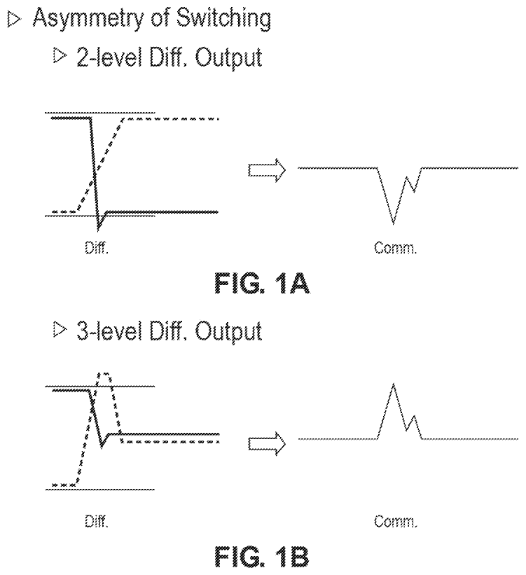

FIG. 1A shows an exemplary graph illustrating asymmetry of switching a 2-level differential output, in accordance with some embodiments of the disclosure provided herein. There may be no common mode change, and in this case positive and negative outputs may match perfectly. In reality, maintaining good matching may be difficult because of fast transition speed. It may be hard to keep good matching over a wide PVT variation.

FIG. 1A depicts an example of asymmetry of switching. When one transistor transitions states (e.g., open to closed) faster than the other transistor is series, the common output is affected asymmetrically. Here, one of ordinary skill can see that the slew rate of the voltage of the solid line is much quicker. It also has some inherent overshoot. The result is depicted in combination on the common mode.

FIG. 1B shows an exemplary graph illustrating asymmetry of switching a 3-level differential output, in accordance with some embodiments of the disclosure provided herein. FIG. 1B depicts an example of asymmetry of switching in a 3-level differential output on the resultant common mode. The common mode error in the present embodiment is caused by overshoot, slew rate difference and transistor resistance imbalance. As stated, these all can be exacerbated by changes in PVT during operation.

Therefore, embodiments herein may relate to a transition-edge common-mode feedback mechanism that relates to directly modulating ON resistance of switches by common-mode feedback to switch gates. Embodiments may have a variety of advantages such as: no series device; no output amplitude degradation; no output resistance increase; very fast feedback loops because a switching transition is very fast; and enabling the feedback amplifier only during the switching transition which may make the additional power relatively small (although in other embodiments the amplifier may stay powered up if power consumption is not a concern).

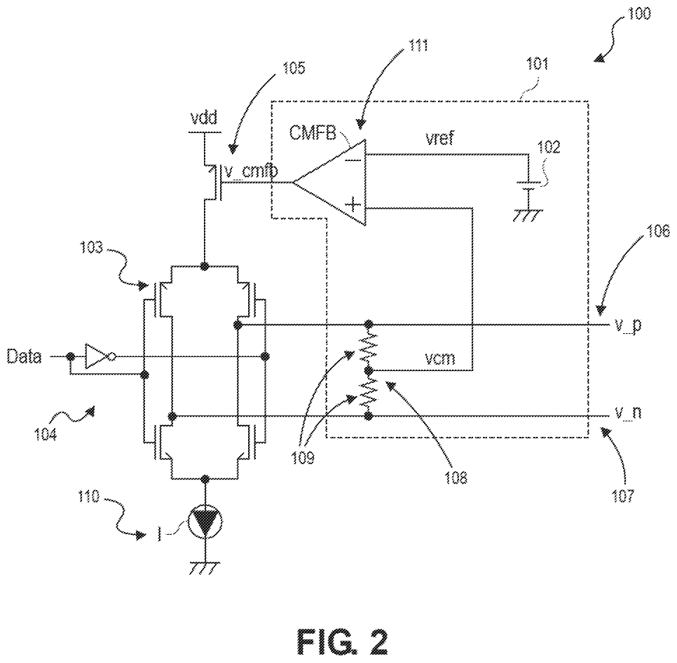

FIG. 2 is an exemplary circuit demonstrating LVDS common mode feedback, in accordance with some embodiments of the disclosure provided herein. LVDS common mode feedback circuit 100 comprises feedback transistor 105, full bridge differential amplifier 103, data node 104, current source 110, and CMFB circuit 101.

In operation, data node 104 receives data on the left half bridge amplifier, while the data is inverted on the right half bridge amplifier. Current source 110 set the current such that outputs remain relatively constant. As is known in the LVDS art, outputs are taken at positive output 106 and negative output 107. Their magnitude and sign depend on the current pathway and direction which is controlled by the transistors in full bridge differential amplifier 103.

CMFB circuit 101 comprises error amp 111, reference voltage source 102, resistor ladder 109 and common mode feedback node 108. In operation, positive output 106 and negative output 107 are compared using resistor ladder 109. Ideally, resistors in ladder 109 are equal. Accordingly, common mode voltage should be equal to the that of vref produced by reference voltage source 102. In practice, resistor values can be adjusted to compensated for manufacturing differences.

In operation, the feedback loop is complete by comparing vref with vcm, the common mode voltage on the common mode feedback node 108. These voltages are compared at differential amp 111, and their difference is compensated for at feedback transistor 105.

The present embodiment can be widely used for LVDS and represents a closed loop solution. As can be appreciated by one of ordinary skill in the art, tail current source is modulated (compensated) to stabilize the common mode. The drawbacks of the present configuration is an additional series device, CMFB circuit 101. This additional series device produces an output swing is reduced by the tail current source. The is an appreciated result of having the resistor ladder 109 in parallel with a typical output receiver which typically has a very high resistance.

Furthermore, output on resistance gets larger by the tail current source. Compared to differential output stage 103 is directly connected to VDD or GND, and there is a tail current which is connected in series. Due to the series connection, output resistance increases. This limits a maximum possible output current and/or output voltage swing. The output resistance increase, the output current limit, and/or the output voltage swing are potential drawbacks of adding series device for CMFB if it is used for delivering power in a class-D amplifier.

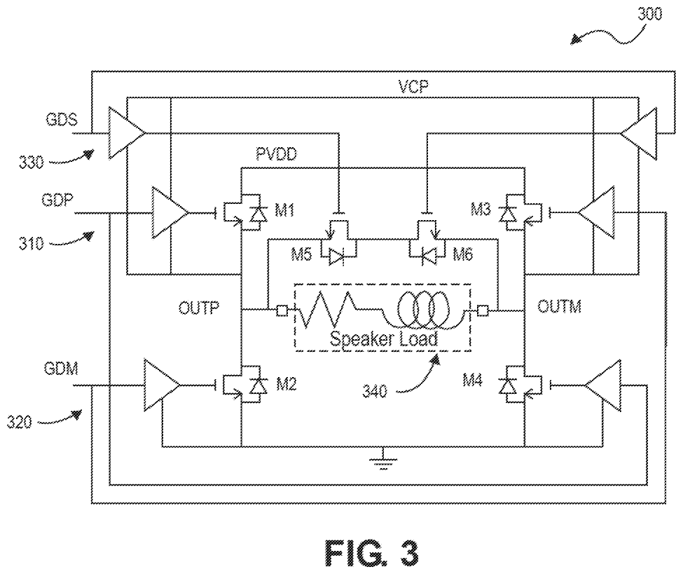

FIG. 3 is an exemplary circuit demonstrating common-mode free binary modulation, in accordance with some embodiments of the disclosure provided herein. Common-mode free binary modulation circuit 300 is a 3-level output stage with middle shunting switch which comprises GDS 330, GDP 310, GDM 320 and speaker load 340. In operation, control inputs are received on GDP 310 and GDM 320. GDS 330 act to control mid-switches M5 and M6. The mid-switch enables the third output level 0V output across the load, in addition to conventional two positive and negative output levels. Common mode during the 0V output level and transition are decided without feedback and may vary depend on PVT errors.

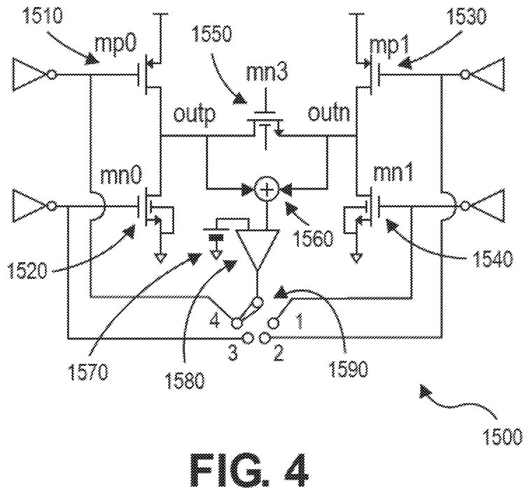

FIG. 4 is an exemplary circuit demonstrating common-mode feedback (CMFB) during edge transition in a 3-level signaling system and sharing one error amp for the CMFB among the switches, in time division fashion, in accordance with some embodiments of the disclosure provided herein. CMFB feedback circuit 1500 comprises transistor mp0 1510, transistor mn0 1520, transistor mp1 1530, transitory mn1 1540, mid-switch mn3 1550, adder circuit 1560, vref voltage source 1570, error amp 1580, and multiplex switch network 1590.

In one or more embodiments, the transistors are mosfets; however, any transistor or suitable switch in not beyond the scope of the present disclosure. As is known in the art, the present embodiment could be considered two half bridges or an H-bridge. However, an H-bridge typically has the load between the two half bridges. Whereas, differential outputs in the present embodiments are taken at the midpoint in the left and right half bridges.

In some embodiments, the load of the H-bridge is a transducer. A transducer is a device that converts energy from one form to another. Usually a transducer converts a signal in one form of energy to a signal in another. Transducers are often employed at the boundaries of automation, measurement, and control systems, where electrical signals are converted to and from other physical quantities (energy, force, torque, light, motion, position, etc.). The process of converting one form of energy to another is known as transduction.

In other embodiments, the two half-bridges forming the H-bridge drive one or more actuators. An actuator is a component of a machine that is responsible for moving and controlling a mechanism or system, for example by opening a valve. In simple terms, it is a “mover.”

An actuator requires a control signal and a source of energy. The control signal is relatively low energy and may be electric voltage or current, pneumatic or hydraulic pressure, or even human power. Its main energy source may be an electric current, hydraulic fluid pressure, or pneumatic pressure. When it receives a control signal, an actuator responds by converting the source's energy into mechanical motion.

An actuator is the mechanism by which a control system acts upon an environment. The control system can be simple (a fixed mechanical or electronic system), software-based (e.g. a printer driver, robot control system), a human, or any other input.

In yet other embodiments, the H-bridge is configured to drive a voice coil motor (VCM). A voice coil (consisting of a former, collar, and winding) is the coil of wire attached to the apex of a loudspeaker cone. It provides the motive force to the cone by the reaction of a magnetic field to the current passing through it. The term is also used for voice coil linear motors, such as those used to move the heads inside hard disk drives, which produce a larger force and move a longer distance but work on the same principle.

Voice Coil Motors (VCM), also called Voice Coil Actuators (VCA), are a very mature design that utilizes a magnet and yoke in conjunction with a coil. The coil and magnet are concentric about a common axis and there exists an engineered magnetic return path.

The coil is typically connected to a mechanism which translates the coil's linear motion into a beneficial action. For example, a conventional loud-speaker uses a voice coil motor to drive a cone which converts the coil's oscillating motion into sound energy.

The typical characteristics of a voice coil motor are a round coil, concentric with and located in a gap where a radial magnetic field is present. This field is generally developed by a permanent magnet located within the structure. The interaction between the coil's magnetic field and the magnetic field in the gap is what gives rise to the linear force acting on the coil. (The coil's magnetic field is due to the current flowing in coil.) The magnet's position within the unit, the type of magnet, the surrounding structure, etc., can influence the nomenclature of the unit.

Originally, most VCMs were similar to a loud-speaker's design. This design uses a gap whose axial length is short and the magnetic field density in the gap is very high. Because of the short gap length, this style required a longer axial length coil to create any reasonable “stroke” or axial travel. Newer designs utilized longer axial length gaps, lower magnetic field densities, and shorter coils using fewer turns of wire. This means that more of the coil operated in the gap, resulting in a mass and resistance reduction. Lower mass equals better acceleration and “settling” and lower resistance translates into greater linearity.

When a VCM/Actuator is coupled with an appropriate feedback device, amp, and controller, precise position, velocity, and acceleration control is possible. When a VCM is used in this geometry it is often referred to as a Positioning Stage or VCM Linear Stage.

Still in other embodiments, the H-bridge can be used to power stepper motors. A stepper motor, also known as step motor or stepping motor, is a brushless DC electric motor that divides a full rotation into a number of equal steps. The motor's position can then be commanded to move and hold at one of these steps without any position sensor for feedback (an open-loop controller), as long as the motor is carefully sized to the application in respect to torque and speed.

In yet even further embodiments, the present disclosure is suitable for use in magnet motors, such as, permanent magnet and stator motors. In particular, the permanent magnet (PMDC) brushed DC motor is generally much smaller and cheaper than its equivalent wound stator type DC motor cousins as they have no field winding. In permanent magnet DC (PMDC) motors these field coils are replaced with strong rare earth (i.e. Samarium Cobolt, or Neodymium Iron Boron) type magnets which have very high magnetic energy fields.

The use of permanent magnets gives the DC motor a much better linear speed/torque characteristic than the equivalent wound motors because of the permanent and sometimes very strong magnetic field, making them more suitable for use in models, robotics and servos.

Although DC brushed motors are very efficient and cheap, problems associated with the brushed DC motor is that sparking occurs under heavy load conditions between the two surfaces of the commutator and carbon brushes resulting in self generating heat, short life span and electrical noise due to sparking, which can damage any semiconductor switching device such as a MOSFET or transistor.

Any of the foregoing and preceding applications can be used in MEMS devices. Microelectromechanical systems (MEMS), also written as micro-electro-mechanical systems (or microelectronic and microelectromechanical systems) and the related micromechatronics and microsystems constitute the technology of microscopic devices, particularly those with moving parts. They merge at the nanoscale into nanoelectromechanical systems (NEMS) and nanotechnology. MEMS are also referred to as micromachines in Japan and microsystem technology (MST) in Europe.

When the differential output changes from Positive to Zero, mp0 and mn1 change from On to Off. Then mn3 is closed to make the differential output zero volts. During the transition, if the resistance of both mp0 and mn1 match, the output common mode is VDD/2. If the mp0 gate is driven independently, the mn1 gate can be controlled such that the mn1 resistor matches the mp0 resistor by using a common mode feedback (CMFB). At least one transistor is controlled by CMFB during the transition, and the transistor can be selected from one of mp0, mp1, mn0 and mn1 using a multiplex switch network 1590. The transistors mp0, mp1, mn0, and mn1 share a subset of the CMFB circuit including the adder circuit 1560, the vref voltage source 1570 and the error amp 1580. Similarly, other transition edges include changes in the various transistors from On to Off. Various transition edges include changes from Zero to Positive, Negative to Zero, and Zero to Negative. For example, when differential output changes from Zero to Positive, mp0 and mn1 change from Off to On, and mn3 is opened.

In various examples, the error amp 1580 is static and is always turned on. In some examples, the error amp 1580 is dynamic, and is repeatedly turned on and off. In some examples, the error amp 1580 is a gm stage.

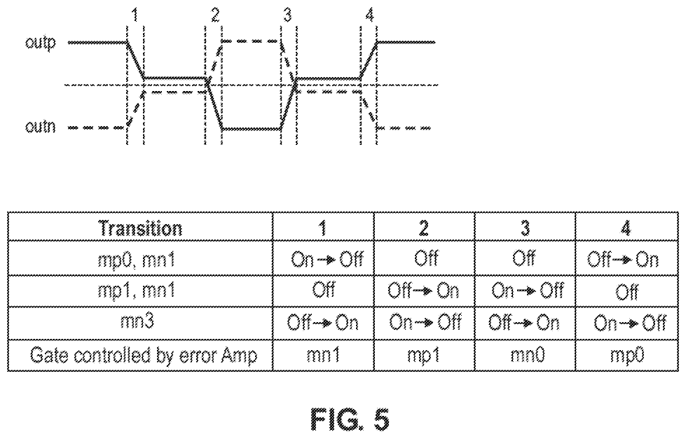

FIG. 5 illustrates an exemplary graph and corresponding timing table of edge transition in 3-level signaling system, in accordance with some embodiments of the disclosure provided herein. It is noted that the error amp's output is switched to different output field effect transistors' (FET's) gates depending on direction of transition.

FIGS. 5 illustrate an example of a way of sharing one error amp for all possible edge transitions. The edge transition can be categorized into 4 patterns. Depending on which edge is happening, one or more transistors are controlled by the error amp are selected.

On the edge two outputs are approaching to center level (1 or 3), low side nmos which is changing the state from On to Off to on is selected. On the edge where two outputs departing from center level, high side pmos which state is changing from Off to ON is selected.

In some embodiments, feedback is controlled through the gate. In other embodiments, common mode feedback can be controlled through the drain or source of the transistors. Typically, in a preferred embodiment, the common mode feedback is controlled through output of the output stage. However, feedback which is derived anywhere in the signal path is not beyond the scope of the present invention.

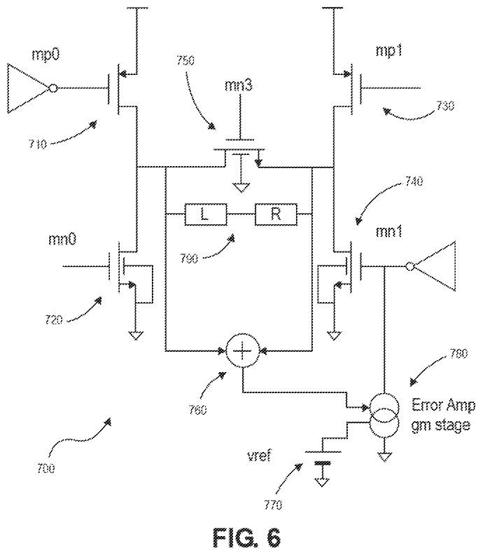

FIG. 6 is an exemplary circuit demonstrating common-mode feedback (CMFB) during edge transition in a 3-level signaling system, in accordance with some embodiments of the disclosure provided herein. CMFB feedback circuit 700 comprises transistor mp0 710, transistor mn0 720, transistor mp1 730, transistor mn1 740, mid-switch mn3 750, load 790, adder circuit 760, vref voltage source 770, and error amp 780.

In one or more embodiments, the transistors are mosfets; however, any transistor or suitable switch in not beyond the scope of the present disclosure. As is known in the art, the present embodiment could be considered two half bridges or an H-bridge. However, an H-bridge typically has the load between the two half bridges. Whereas, differential outputs in the present embodiments are taken at the midpoint in the left and right half bridges.

FIG. 6 has 3-level (Positive, Negative and Zero) outputs in terms of differential voltage across the load 790. When output is Positive, mp0 and mn1 are ON. The left terminal of the load is connected to VDD and the right terminal of the load is connected to GND. Thus, voltage across the load is VDD-GND. When output is Negative, mp1 and mn0 are ON. The left terminal of the load is connected to GND and the right terminal of the load is connected to VDD. Thus, voltage across the load is GND-VDD. During the Positive and Negative cases, common mode of the outputs is set by VDD/2. According to various examples, common mode of the outputs is set by VDD/2 because if one output is VDD, the other output is GND. When output is Zero, mn3 is ON. Voltage across the load becomes zero. Because the circuit formed by mn3 and the load is floating from the VDD/GND rail, the voltage of the circuit is set relative to VDD/GND.

In a transition from Positive to Zero output, if resistance of mp0 and mn1 are kept equal during the transition period, common mode of the outputs remain at VDD/2. The left terminal of the load settles to VDD/2 from VDD and the right terminal of the load settles to VDD/2 from GND at the end of the transition. Although the circuit formed by mn3 and the load is floating from the VDD/GND rail, in practice there is a parasitic cap on the output noted to the supply rail. The parasitic cap can maintain the common mode voltage to VDD/2 during the Zero output period. For other transitions (Zero to Positive, Negative to Zero, and Zero to Negative), if a pair of transistors on a diagonal (mp0-mn1, or mp1-mn0) maintain equal resistance during the transition, the common mode is maintained at VDD/2.

The adder circuit 760 and the error amp 780 are described in greater detail below.

The motivation of the present embodiment is that current of mp0 710 and mp1 730 gates can be driven independently. Mn1 740 and mn0 720 gate can be adjusted by the gm cell (error amp 780) so as to maintain the common mode equal to vref. The present embodiment absorbs PVT changes of mp0 710 and mn1 740 (and mp1 730, mn0 720 in the reverse current direction).

The motivation of choosing feedback of mn1 730 and mn0 720 is that nmos has more gain than pmos for the same gate parasitic capacitor. In theory, controlling at least one of the gates (except for mn3) works as a common mode feedback. In other embodiments, any nmos and pmos gates can be used.

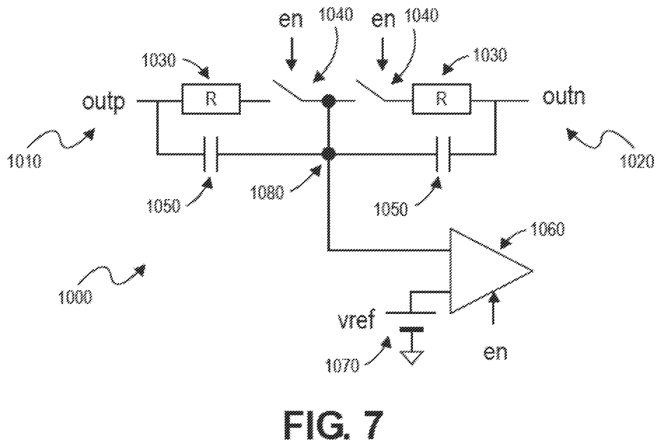

FIG. 7 is an exemplary circuit demonstrating common-mode extraction using a resistor network, in accordance with some embodiments of the disclosure provided herein. Common-mode extractor 1000 comprises differential amp 1060, reference voltage source 1070, output p node 1010, output n node 1020, resistors 1030, switches 1040, capacitors 1050, and extracted common mode node 1080.

In practice, the common mode is extracted through resistors 1030 primarily for the DC component, in one or more embodiments. Since a preferred embodiment includes feedback control during switching, a high frequency component detection is highly desirable. Accordingly, capacitors 1050 wired in parallel serve this purpose—that is, high frequency detection during switching changes.

Summing node extracts both high frequency (HF) components and DC offset. The series switches 1040 are closed during the Zero output and both high and low frequencies are compared and compensated for differential amplifier 1060. The output therefrom is negatively fed back as is known in the art.

The series switches 1040 can be open during Positive and/or Negative outputs to save the power due to current flow through the resistor 1030. In some implementations, the series switches are open even during transitions because the HF component needed for the CMFB can be extracted by the capacitors 1050.

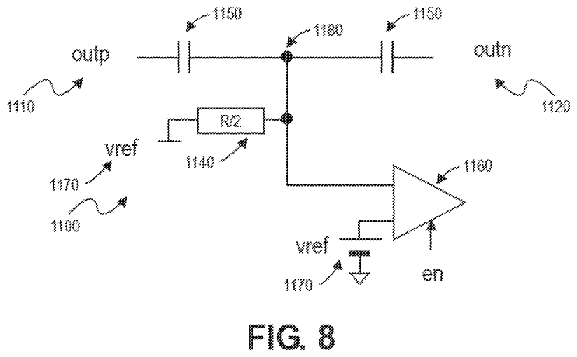

FIG. 8 is an exemplary circuit demonstrating common-mode extraction using a capacitor network, in accordance with some embodiments of the disclosure provided herein. Common-mode extractor 1100 comprises differential amp 1170, reference voltage source 1170, output p node 1110, output n node 1120, capacitors 1150, resistor 1140, and extracted common mode node 1180.

Capitalizing on the notion that common-mode feedback on needs high frequency component, a simple capacitor summer can be used in one or more embodiments. This, of course, exclude DC components which can be set in other ways known in the art. In operation, the extracted common mode node is set to desired voltage through vref reference voltage source 1170 and resistor 1140, which in the present embodiment is half of the resistance of the previous embodiment.

FIG. 8 depicts an example of common mode extraction by capacitor. In this embodiment, the edge CMFB may only need high-frequency components. A simple capacitor summer may be sufficient. One or more DC components may be set in accordance with some other technique.

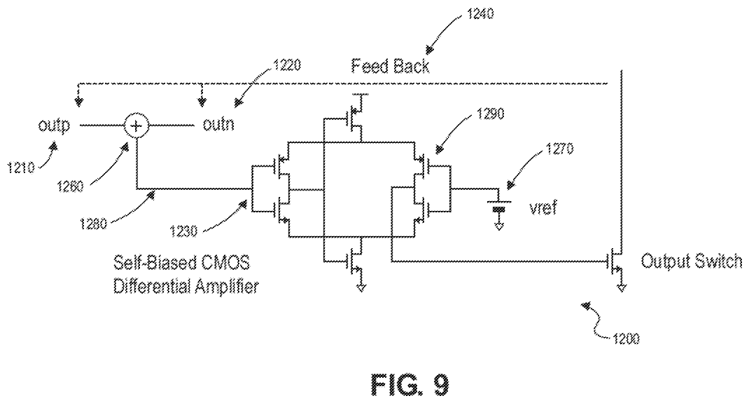

FIG. 9 is an exemplary circuit depicting an error amplifier implementation, in accordance with some embodiments of the disclosure provided herein. Error amp 1200 comprises self-biased CMOS differential amp 1230, reference voltage source 1270, output p node 1210, output n node 1220, adder circuit 1260, extracted common mode output 1280, feedback loop 1240, and feedback amp 1290.

The present embodiment yields superior output current capability compared to fixed biased tail current differential pair. Tail current of the self-biased cmos differential amplifier is dynamically increased depend on the input signal. But the amplifier itself is known method. It is also efficient in terms transconductance, gm.

FIG. 9 illustrates an example of an error amplifier implementation. Specifically, the embodiment may include or relate to self-biased CMOS differential amplifier. The embodiment may be efficient in terms of gm. The embodiment may include superior current output capability with respect to a fixed bias tail current differential pair.

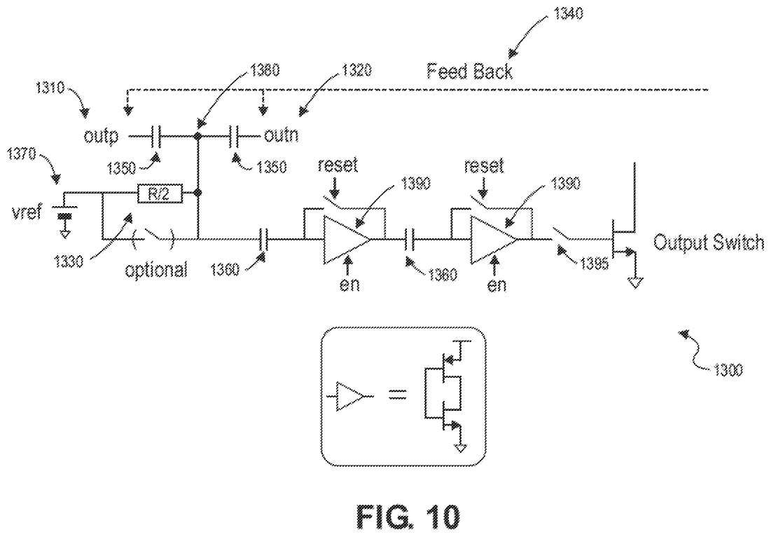

FIG. 10 is an exemplary circuit depicting an error amplifier implementation, in accordance with some embodiments of the disclosure provided herein. In one or more embodiments, error amp 1300 comprises self-biased CMOS differential amps 1390, reference voltage source 1370, output p node 1310, output n node 1320, adder circuit 1360, extracted common mode output 1380, capacitors 1360, summing capacitors 1350, feedback loop 1340, and output gate switch 1395.

In practice, inverters can be summing used which are more efficient in terms of transconductance. Error amp stores DC reference voltage into 1360 first before switching starts. During the time, all reset switches are closed. Once the output stage start transition, the reset switches are open. The error amp amplifies the difference from the stored DC reference voltage in 1360 with common mode AC component extracted from 1350. Thus, the first inverter can compare difference between Vref and common mode component. Difference between them are the common mode error which we would like to suppress. In one or more embodiments, error amp functionality is done at switched cap in front of first amplifier.

In some embodiments, reset switches make the circuit it auto zeroing. They establish an operation point of the inverter and let capacitor 1360 store Vref and offset of the inverter amplifiers.

FIG. 10 illustrates an alternative example of an error amplifier implementation. In this embodiment, an inverter may be used, which may be even more efficient in terms of gm. The error amp. Function may be performed at the switched capacitor in front of the first amplifier. This embodiment may be auto-zeroing.

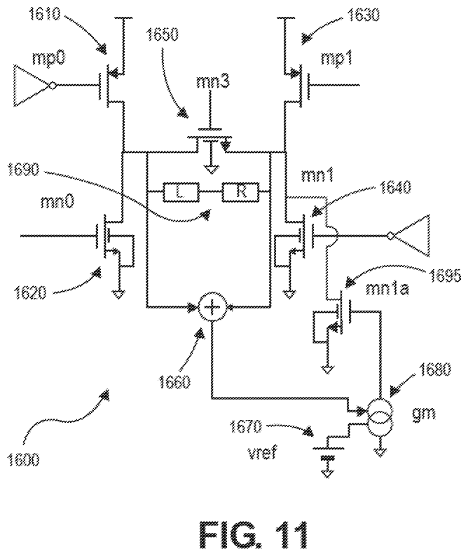

FIG. 11 is an exemplary circuit demonstrating common-mode feedback (CMFB) during edge transitions, in accordance with some embodiments of the disclosure provided herein. Parallel device here is mn1a. Instead of control mn1 gate, we can add mn1a in parallel. Mn1a is typically much smaller than mn1 and easier to drive by error amplifiers. Mn1a is internal device.

CMFB circuit 1600 comprises transistor mp0 1610, transistor mn0 1620, transistor mp1 1630, transitory mn1 1640, mid-switch mn3 1650, adder circuit 1660, vref voltage source 1670, error amp 1680, parallel controller 1695, and load 1690. In some examples, the load is a series connection of inductor L and resistor R which is a typical equivalent circuit for class-D audio applications.

In one or more embodiments, the transistors are mosfets; however, any transistor or suitable switch in not beyond the scope of the present disclosure. As is known in the art, the present embodiment could be considered two half bridges or an H-bridge. However, an H-bridge typically has the load between the two half bridges. Whereas, differential outputs in the present embodiments are taken at the midpoint in the left and right half bridges.

In practice, current runs down the leg through mp0 1610 over mn3 1650 and down through mn1 1640. This would, of course, be one current direction in a 2-level signal system. The counter current is such a runs down the leg through mp1 1630 over mn3 1650 and down through mn0 1620.

In one or more alternate embodiments, parallel controller 1695 acts control the feedback current of the common mode. As previously described, any of the transistors can be used as a feedback controller. This, of course, is dependent on the switching cycle. That is, a transistor which is turned off (i.e., not used) during edge transistor would not be suitable a feedback controller.

FIG. 11 depicts an example of a parallel controller, in accordance with various embodiments herein. FIG. 11 may include a parallel-connected switch which switches the gate that is in the control loop of the CMFB.

FIG. 11 is a special case of FIG. 4 where only one of the transitions are being captured. In various examples, there are parallel devices for the other output devices: 1620, 1610, 1630, 1640.

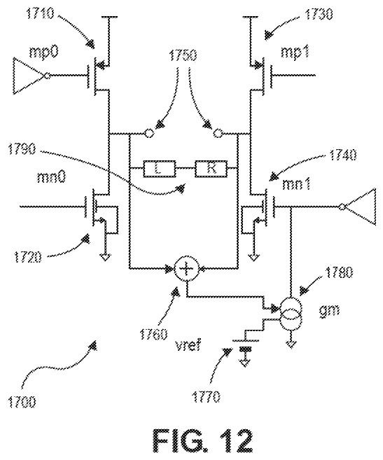

FIG. 12 depicts an example of the CMFB during the transition edge, and can be used in common mode stabilization in a 2-level signaling system, in accordance with some embodiments of the disclosure provided herein. In one or more embodiments, CMFB circuit 1700 can be used for a 2-level output stage which is widely used for class-D amp or data transmission. This will be discussed in more detail later in the disclosure.

CMFB circuit 1700 comprises transistor mp0 1710, transistor mn0 1720, transistor mp1 1730, transitory mn1 1740, output nodes 1750, adder circuit 1760, vref voltage source 1770, error amp 1780, and load 1790. The load is series connection of inductor L and resistor R which is typical equivalent circuit for class-D audio application.

FIG. 12 illustrates the transition edge when mp0 and mn1 are switching, according to various embodiments of the disclosure. CMFB adjusts mn1's transition speed such that a resistor change of m1 is matched to the resistor change of mp0. During the other side of transition edge, when mp1 and mn0 are switching, the gate of mn0 can be controlled by a gm stage and form a CMFB loop, so as to stabilize the output common mode.

FIG. 12 depicts an example of a 2-level output stage, in accordance with various embodiments. The embodiment of FIG. 4 may be used for an ordinal 2-level output stage, for example as may be used in a class-D amplifier or in data transmission.

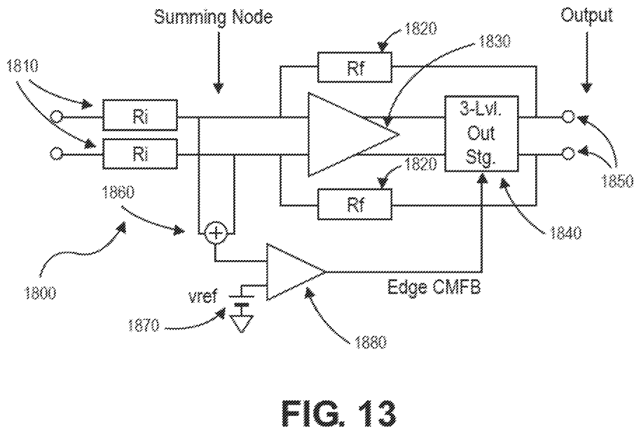

FIG. 13 is an exemplary common-mode stabilization circuit with summing node which can be used in during edge transition in a 3-level signaling system, in accordance with some embodiments of the disclosure provided herein. Common-mode stabilization circuit 1800 comprises input resistors 1810, adder circuit 1860, vref voltage source 1870, feedback error amplifier 1880, feedback resistors 1820, primary differential amplifier 1830, 3-level output stage 1840, and outputs 1850.

FIG. 13 relates to summing node CM stabilization, in accordance with various embodiments. The technique may apply to stabilize other than output node. CM sense node can be separate from CM force node. The schematic of FIG. 13 may be an example where sensing different node form output. This embodiment may relate to sensing summing node CM and force output so as to stabilize the summing node CM. If one wants to stabilize the summing node most, it can be one of options.

One of ordinary skill will appreciate that the common mode feedback inputs can come from 1810 or anywhere else in the signal chain. This is different from some previous embodiments which the feedback is typically taken from the output stage.

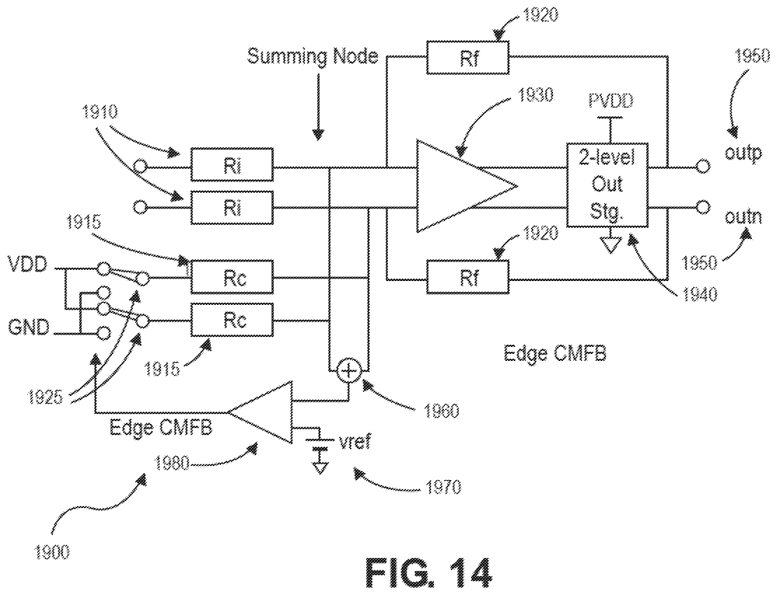

FIG. 14 is an exemplary circuit configured to stabilizing a summing node by replicating of output stage with CMFB instead of controlling the output stage, in accordance with some embodiments of the disclosure provided herein. Common-mode stabilization circuit 1900 comprises input resistors 1910, adder circuit 1960, vref voltage source 1970, feedback error amplifier 1980, feedback resistors 1920, primary differential amplifier 1930, 2-level output stage 1940, outputs 1950, switched resistors 1915, and switches 1925. Switch resistors 1915 and switches 1925 act as the replicated 2-level output stage. In some examples, the switches 1925 implement a round-robin switching.

FIG. 14 exemplifies a point to extract a common mode. It can be extracted from another point other than the output. In some examples, the summing node is often a point one wants to stabilize most. In some implementations, the input to the adder circuit 1960 is feedback from the output stage. In other implementations, the input to the adder circuit 1960 comes from an upstream source.

FIG. 14 further relates to summing node CM stabilization. In some implementations, summing node CM is stabilized but output CM is not stabilized; sensing CM of summing node and forcing CM of summing node. As one skilled in art can appreciate, the present disclosure is readily applied to pulse width modulation (PWM) and class-D amplifiers, in one or more embodiments.

Pulse-width modulation (PWM), or pulse-duration modulation (PDM), is a method of reducing the average power delivered by an electrical signal, by effectively chopping it up into discrete parts. The average value of voltage (and current) fed to the load is controlled by turning the switch between supply and load on and off at a fast rate. The longer the switch is on compared to the off periods, the higher the total power supplied to the load. Along with maximum power point tracking (MPPT), it is one of the primary methods of reducing the output of solar panels to that which can be utilized by a battery. PWM is particularly suited for running inertial loads such as motors, which are not as easily affected by this discrete switching, because their inertia causes them to react slowly. The PWM switching frequency has to be high enough not to affect the load, which is to say that the resultant waveform perceived by the load must be as smooth as possible.

The rate (or frequency) at which the power supply must switch can vary greatly depending on load and application. For example, switching has to be done several times a minute in an electric stove; 120 Hz in a lamp dimmer; between a few kilohertz (kHz) and tens of kHz for a motor drive; and well into the tens or hundreds of kHz in audio amplifiers and computer power supplies.

The main advantage of PWM is that power loss in the switching devices is very low. When a switch is off there is practically no current, and when it is on and power is being transferred to the load, there is almost no voltage drop across the switch. Power loss, being the product of voltage and current, is thus in both cases close to zero. PWM also works well with digital controls, which, because of their on/off nature, can easily set the needed duty cycle. PWM has also been used in certain communication systems where its duty cycle has been used to convey information over a communications channel.

A class-D amplifier or switching amplifier is an electronic amplifier in which the amplifying devices (transistors, usually MOSFETs) operate as electronic switches, and not as linear gain devices as in other amplifiers. They operate by rapidly switching back and forth between the supply rails, being fed by a modulator using pulse width, pulse density, or related techniques to encode the audio input into a pulse train. The audio escapes through a simple low-pass filter into the loudspeaker. The high-frequency pulses are blocked. Since the pairs of output transistors are never conducting at the same time, there is no other path for current flow apart from the low-pass filter/loudspeaker. For this reason, efficiency can exceed 90%.

Therefore, embodiments herein may relate to a transition-edge common-mode feedback mechanism that relates to directly modulating ON resistance of switches by common-mode feedback to switch gates. Embodiments may have a variety of applications, such as, LVDS, PWM, class-D amplifiers, any differential amplification. However, application to arts not explicitly enumerated are not beyond the scope of the present invention.

### SELECT EXAMPLES

Example 1 provides a common-mode feedback circuit comprising: a differential amplifier having a positive output and negative output; an adder circuit configured to extract the common mode from the positive output and negative output; a feedback amplifier configured to correct the common mode; an output stage; and a switching network, the switching network configured to control the correction of the common mode only during transitions in the differential amplifier.

Example 2 provides a circuit according to one or more of the preceding and/or following examples, further comprising a FET connected in parallel to the output stage.

Example 3 provides a circuit according to one or more of the preceding and/or following examples, further comprising an edge detector circuit.

Example 4 provides a circuit according to one or more of the preceding and/or following examples, wherein the edge detector is configured to capture high frequency components.

Example 5 provides a circuit according to one or more of the preceding and/or following examples, wherein the adder circuit comprises two or more resistors wired in series.

Example 6 provides a circuit according to one or more of the preceding and/or following examples, wherein the adder circuit further comprises two more capacitors wired in series with one another and wired in parallel with the two or more resistors.

Example 7 provides a circuit according to one or more of the preceding and/or following examples, further comprising a voltage reference source, wherein the feedback amplifier is further configured to compare the voltage reference source with the common mode.

Example 8 provides a circuit according to one or more of the preceding and/or following examples, wherein the adder circuit comprises two or more capacitors wired in series.

Example 9 provides a circuit according to one or more of the preceding and/or following examples, wherein the adder circuit further comprises a resistor having one terminal wired in between the two or more capacitors wired in series.

Example 10 provides a method for providing common mode feedback in a differential amplifier, the method comprising: producing a first signal in the differential amplifier; producing a second signal in the differential amplifier; extracting the common mode from the first and second signal; comparing the common mode to a reference voltage; and feeding back the difference between the common and the reference voltage in the differential amplifier.

Example 11 provides a method according to one or more of the preceding and/or following examples, further comprising switching one or more transistors in the differential amplifier.

Example 12 provides a method according to one or more of the preceding and/or following examples, further comprising detecting an edge in the one or more transistors.

Example 13 provides a method according to one or more of the preceding and/or following examples, wherein the switching is configured such that feedback is asserted during edge transitions.

Example 14 provides a method according to one or more of the preceding and/or following examples, wherein the switching is configured such that the feeding back occurs during edge transitions.

Example 15 provides a method according to one or more of the preceding and/or following examples, wherein the switching is configured such that feedback is only asserted during edge transitions.

Example 16 provides a method according to one or more of the preceding and/or following examples, wherein the switching is configured such that the feeding back only occurs during edge transitions.

Example 17 provides a method according to one or more of the preceding and/or following examples, wherein the common mode extraction is engendered by at least two resistors wired in series.

Example 18 provides a method according to one or more of the preceding and/or following examples, wherein extracting the common mode includes extracting the common mode using at least two resistors wired in series.

Example 19 provides a method according to one or more of the preceding and/or following examples, wherein the common mode extraction further comprises at least two capacitors wired in series with one another and wired in parallel with the at least two resistors.

Example 20 provides a method according to one or more of the preceding and/or following examples, wherein extracting the common mode includes extracting the common mode using at least two capacitors wired in series with one another and wired in parallel with the at least two resistors.

Example 21 provides a method according to one or more of the preceding and/or following examples, wherein extracting the common mode includes extracting the common mode using at least two capacitors wired in series.

Example 22 provides a method according to one or more of the preceding and/or following examples, wherein the common mode extraction is engendered by at least two capacitors wired in series.

Example 23 provides a method according to one or more of the preceding and/or following examples, wherein the feeding back is controlled via a transistor wired in parallel to the differential amplifier.

Example 24 provides a method according to one or more of the preceding and/or following examples, wherein the feedback is controlled via a transistor wired in parallel to the differential amplifier.

Example 25 provides a method according to one or more of the preceding and/or following examples, further comprising outputting the first and second signal to an output stage.

Example 26 provides a circuit for providing common mode feedback in a differential amplifier, the circuit comprising: means for producing a first signal in the differential amplifier; means for producing a second signal in the differential amplifier; means for extracting the common mode from the first and second signal; means for comparing the common mode to a reference voltage; and, means for feeding back the difference between the common and the reference voltage in the differential amplifier.

Example 27 provides a circuit according to one or more of the preceding and/or following examples, further comprising a means for switching one or more transistors in the differential amplifier.

Example 28 provides a circuit according to one or more of the preceding and/or following examples, wherein the feedback amplifier is one of static and dynamic.

Example 29 provides a circuit according to one or more of the preceding and/or following examples, wherein the feedback amplifier is a gm stage.

Example 30 provides a circuit according to one or more of the preceding and/or following examples, further comprising an error amplifier, and wherein the error amplifier is at least one of a static amplifier, a dynamic amplifier, and a gm stage.

Example 30 provides a circuit according to one or more of the preceding and/or following examples, further comprising an input, wherein the input comes from a summing junction of a modulator.

Example 31 provides a circuit according to one or more of the preceding and/or following examples, wherein the input includes an error, and wherein the summing junction corrects for the error.

Example 32 includes or relates to edge common mode stabilization, in accordance with various embodiments or examples herein.

Example 33 relates to low and high frequency common mode extraction and stabilization, in accordance with various embodiments or examples herein.

Example 34 relates to summing node common mode stabilization, in accordance with various embodiments or examples herein.

Example 35 relates to an operating sequence depending on current direction, in accordance with various embodiments or examples herein.

Example 36 relates to any of examples 1-35, or some other example, and including 3-levels, 2-levels, or 5 levels of modulation, in accordance with various embodiments or examples herein.

Example 37 relates to any of examples 1-36, or some other example, wherein the error feedback amplifier may be static or dynamic in nature, in accordance with various embodiments or examples herein.

Example 38 includes an apparatus that includes or relates to any of embodiments 1-37, or some other concepts or embodiments discussed herein.

Example 39 includes an apparatus comprising means to implement any of embodiments 1-38, or some other concepts or embodiments discussed herein.

Example 40 includes a method for implementing or manufacturing any of embodiments 1-39, or some other concepts or embodiments discussed herein.

Example 41 includes one or more non-transitory computer-readable media comprising instructions that, upon execution of the instructions by an electronic device, are to cause the electronic device to implement or manufacture any of embodiments 1-40, or some other concepts or embodiments discussed herein.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein.

Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more embodiments of the subject matter disclosed herein. These embodiments are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the embodiments introduced herein. The PHOSITA will also recognize that such equivalent constructions do not depart from the spirit and scope of the present disclosure, and that they may make various changes, substitutions, and alterations herein without departing from the spirit and scope of the present disclosure.

The above-described embodiments may be implemented in any of numerous ways. One or more aspects and embodiments of the present application involving the performance of processes or methods may utilize program instructions executable by a device (e.g., a computer, a processor, or other device) to perform, or control performance of, the processes or methods.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above.

The computer readable medium or media may be transportable, such that the program or programs stored thereon may be loaded onto one or more different computers or other processors to implement various ones of the aspects described above. In some embodiments, computer readable media may be non-transitory media.

Note that the activities discussed above with reference to the FIGURES which are applicable to any integrated circuit that involves signal processing (for example, gesture signal processing, video signal processing, audio signal processing, analog-to-digital conversion, digital-to-analog conversion), particularly those that can execute specialized software programs or algorithms, some of which may be associated with processing digitized real-time data.

In some cases, the teachings of the present disclosure may be encoded into one or more tangible, non-transitory computer-readable mediums having stored thereon executable instructions that, when executed, instruct a programmable device (such as a processor or DSP) to perform the methods or functions disclosed herein. In cases where the teachings herein are embodied at least partly in a hardware device (such as an ASIC, IP block, or SoC), a non-transitory medium could include a hardware device hardware-programmed with logic to perform the methods or functions disclosed herein. The teachings could also be practiced in the form of Register Transfer Level (RTL) or other hardware description language such as VHDL or Verilog, which can be used to program a fabrication process to produce the hardware elements disclosed.

In example implementations, at least some portions of the processing activities outlined herein may also be implemented in software. In some embodiments, one or more of these features may be implemented in hardware provided external to the elements of the disclosed figures, or consolidated in any appropriate manner to achieve the intended functionality. The various components may include software (or reciprocating software) that can coordinate in order to achieve the operations as outlined herein. In still other embodiments, these elements may include any suitable algorithms, hardware, software, components, modules, interfaces, or objects that facilitate the operations thereof.

Any suitably-configured processor component can execute any type of instructions associated with the data to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, an FPGA, an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, processors may store information in any suitable type of non-transitory storage medium (for example, random access memory (RAM), read only memory (ROM), FPGA, EPROM, electrically erasable programmable ROM (EEPROM), etc.), software, hardware, or in any other suitable component, device, element, or object where appropriate and based on particular needs. Further, the information being tracked, sent, received, or stored in a processor could be provided in any database, register, table, cache, queue, control list, or storage structure, based on particular needs and implementations, all of which could be referenced in any suitable timeframe.

Any of the memory items discussed herein should be construed as being encompassed within the broad term ‘memory.’ Similarly, any of the potential processing elements, modules, and machines described herein should be construed as being encompassed within the broad term ‘microprocessor’ or ‘processor.’ Furthermore, in various embodiments, the processors, memories, network cards, buses, storage devices, related peripherals, and other hardware elements described herein may be realized by a processor, memory, and other related devices configured by software or firmware to emulate or virtualize the functions of those hardware elements.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a personal digital assistant (PDA), a smart phone, a mobile phone, an iPad, or any other suitable portable or fixed electronic device.

Also, a computer may have one or more input and output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks or wired networks.

Computer-executable instructions may be in many forms, such as program modules, executed by one or more computers or other devices. Generally, program modules include routines, programs, objects, components, data structures, etc. that performs particular tasks or implement particular abstract data types. Typically, the functionality of the program modules may be combined or distributed as desired in various embodiments.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present application need not reside on a single computer or processor, but may be distributed in a modular fashion among a number of different computers or processors to implement various aspects of the present application.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Computer program logic implementing all or part of the functionality described herein is embodied in various forms, including, but in no way limited to, a source code form, a computer executable form, a hardware description form, and various intermediate forms (for example, mask works, or forms generated by an assembler, compiler, linker, or locator). In an example, source code includes a series of computer program instructions implemented in various programming languages, such as an object code, an assembly language, or a high-level language such as OpenCL, RTL, Verilog, VHDL, Fortran, C, C++, JAVA, or HTML for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

In some embodiments, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example embodiment, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Interpretation of Terms

All definitions, as defined and used herein, should be understood to control over dictionary definitions, definitions in documents incorporated by reference, and/or ordinary meanings of the defined terms. Unless the context clearly requires otherwise, throughout the description and the claims:

“comprise,” “comprising,” and the like are to be construed in an inclusive sense, as opposed to an exclusive or exhaustive sense; that is to say, in the sense of “including, but not limited to”.

“connected,” “coupled,” or any variant thereof, means any connection or coupling, either direct or indirect, between two or more elements; the coupling or connection between the elements can be physical, logical, or a combination thereof.

“herein,” “above,” “below,” and words of similar import, when used to describe this specification shall refer to this specification as a whole and not to any particular portions of this specification.

“or,” in reference to a list of two or more items, covers all of the following interpretations of the word: any of the items in the list, all of the items in the list, and any combination of the items in the list.

the singular forms “a”, “an” and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112(f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular embodiments described above. Various modifications, equivalent processes, as well as numerous structures to which the present invention may be applicable, will be readily apparent to those skilled in the art to which the present invention is directed upon review of the present disclosure.

What is claimed is:

1. A common-mode feedback circuit comprising:
a differential amplifier having a positive output and negative output;
an adder circuit configured to extract the common mode from the positive output and negative output;
a feedback amplifier configured to correct the common mode;
an output stage; and
a switching network, the switching network configured to control the correction of the common mode only during transitions in the differential amplifier.

2. The circuit according to claim 1, further comprising a FET connected in parallel to the output stage.

3. The circuit according to claim 2, further comprising an edge detector circuit.

4. The circuit according to claim 3, wherein the edge detector is configured to capture high frequency components.

5. The circuit according to claim 1, wherein the adder circuit comprises at least two resistors wired in series.

6. The circuit according to claim 5, wherein the adder circuit further comprises at least two capacitors wired in series with one another and wherein the at least two capacitors are wired in parallel with the at least two resistors.

7. The circuit according to claim 1, further comprising a voltage reference source, the feedback amplifier is further configured to compare the voltage reference source with the common mode.

8. The circuit according to claim 1, wherein the adder circuit comprises at least two capacitors wired in series.

9. The circuit according to claim 8, wherein the adder circuit further comprises a resistor having one terminal wired in between the at least two capacitors wired in series.

10. A method for providing common mode feedback in a differential amplifier, the method comprising:
producing a first signal in the differential amplifier;
producing a second signal in the differential amplifier;
extracting the common mode from the first and second signal;
comparing the common mode to a reference voltage; and
feeding back the difference between the common mode and the reference voltage in the differential amplifier.

11. The method according to claim 10, further comprising switching at least one transistor in the differential amplifier.

12. The method according to claim 11, further comprising detecting an edge in the at least one transistor.

13. The method according to claim 12, wherein the switching is configured such that the feeding back only occurs during edge transitions.

14. The method according to claim 10, wherein extracting the common mode includes extracting the common mode using at least two resistors wired in series.

15. The method according to claim 14, wherein extracting the common mode includes extracting the common mode using at least two capacitors wired in series with one another and wired in parallel with the at least two resistors.

16. The method according to claim 10, wherein extracting the common mode includes extracting the common mode using at least two capacitors wired in series.

17. The method according to claim 10, wherein the feeding back is controlled via a transistor wired in parallel to the differential amplifier.

18. The method according to claim 10, further comprising outputting the first and second signal to an output stage.

19. A circuit for providing common mode feedback in a differential amplifier, the circuit comprising:
means for producing a first signal in the differential amplifier;
means for producing a second signal in the differential amplifier;
means for extracting the common mode from the first and second signal;
means for comparing the common mode to a reference voltage; and, means for feeding back the difference between the common and the reference voltage in the differential amplifier.

20. The circuit according to claim 19 further comprising a means for switching one or more transistors in the differential amplifier.
